(19) United States
(12) Patent Application Publication
(10) Pub. No.: US 2025/0174502 A1
(43) Pub. Date: May 29, 2025

(54) PACKAGE SUBSTRATE AND METHOD OF MANUFACTURING THE SAME

(71) Applicant: SAMSUNG ELECTRONICS CO., LTD., SUWON-SI (KR)

(72) Inventor: LIQUN GU, SUZHOU (CN)

(21) Appl. No.: 18/412,432

(22) Filed: Jan. 12, 2024

(30) Foreign Application Priority Data
Nov. 27, 2023 (CN) 202311596607.6

(51) Int. Cl. H01L 23/13; H01L 21/48; H01L 23/498

(52) U.S. Cl. CPC H01L 23/13; H01L 21/4803; H01L 21/481; H01L 23/49827

(57) ABSTRACT

A package substrate includes: a base substrate; a first conductive layer disposed on a first surface of the base substrate; a second conductive layer disposed on a second surface of the base substrate opposite the first surface of the base substrate; a first solder resist layer disposed on the first surface of the base substrate; a second solder resist layer disposed on the second surface of the base substrate; a plurality of contact plugs penetrating the base substrate and electrically connecting the first and second conductive layers; and a plurality of stress relief through holes penetrating the base substrate, the first solder resist layer and the second solder resist layer.

### CROSS-REFERENCE TO RELATED APPLICATION

This application is based on and claims priority under 35 U.S.C. § 119 to Chinese Patent Application No. 202311596607.6, filed on Nov. 27, 2023, in the China National Intellectual Property Administration, the disclosure of which is incorporated by reference herein in its entirety.

### BACKGROUND

### 1. Technical Field

The present disclosure relates to semiconductor packaging, and more particularly to a package substrate and a method of manufacturing the package substrate.

### 2. Discussion of Related Art

During a high-temperature reflow procedure in a semiconductor packaging process, a package substrate may be warped due to heat. Specifically, the package substrate may include multiple layers formed from different materials. In a case where the different materials have different coefficients of thermal expansion (CTEs), there may be a warpage problem in the package substrate due to a mismatch of the CTEs. In addition, a residual stress in the package substrate may be present in the package substrate, and there may be a warpage problem in the package substrate due to the residual stress. A warped package substrate may be prone to contact problems such as non-wet defects between bumps and traces, which may reduce a package quality of the package structure (as illustrated in FIG. 1).

When a package substrate includes a plurality of unit substrates, although a single unit substrate may have a relatively small warping effect, the warping effect may accumulate for the entire package substrate and result in warpage of the package substrate. Warpage of the package substrate at an edge region may be larger than away from the edge region, thereby increasing the risk of poor contact, which may lead to defects such as non-wet defects. For example, for a package substrate including 5×22 unit substrates (i.e., the unit substrates are arranged in a 5×22 matrix), if the warping strength of each unit substrate is 30 μm, the warping strength over the entire package substrate may be as high as 1900 μm, which may affect the package quality.

### SUMMARY

Aspects of the present disclosure may reduce a warpage of a package substrate and improve a package quality.

The present disclosure provides a package substrate having a structure that may reduce a warpage of the package substrate and a method of manufacturing the package substrate.

According to one aspect of the present disclosure, a package substrate divided by a plurality of unit substrates may be provided. The package substrate may include: a base substrate; a first conductive layer disposed on a first surface of the base substrate; a second conductive layer disposed on a second surface of the base substrate opposite to the first surface of the base substrate; a first solder resist layer disposed on the first surface of the base substrate; a second solder resist layer disposed on the second surface of the base substrate; a plurality of contact plugs penetrating the base substrate and electrically connecting the first conductive layer and the second conductive layer; and a plurality of stress relief through holes penetrating the base substrate, the first solder resist layer and the second solder resist layer.

In an embodiment, each of the plurality of stress relief through holes may be disposed as a single through hole extending continuously in a direction parallel to a plane of the package substrate.

In an embodiment, each of the plurality of stress relief through holes may be disposed as a plurality of through holes arranged in a direction parallel to a plane of the package substrate and separated from each other.

In an embodiment, at least a portion of each the plurality of stress relief through holes may be disposed between adjacent unit substrates of the plurality of unit substrates.

In an embodiment, a stress relief through hole of the plurality of stress relief through holes may be disposed on a side of each unit substrate of the plurality of unit substrates.

In an embodiment, a stress relief through hole of the plurality of stress relief through holes may be disposed at a corner portion of each unit substrate of the plurality of unit substrates.

In an embodiment, the plurality of stress relief through holes may be disposed with respect to an entirety of the package substrate, and may be disposed at at least one of four edge regions and at at least one of four corner portions of the package substrate.

In an embodiment, the plurality of stress relief through holes may be at least partially filled with a filler comprising a material having a high modulus and a low coefficient of thermal expansion.

According to another aspect of the present disclosure, a method of manufacturing a package substrate is provided. The method may include: providing a preliminary package substrate including a plurality of unit substrates; and performing an interrupting process on the preliminary package substrate to form a plurality of stress relief through holes penetrating a base substrate, a first solder resist layer and a second solder resist layer of the preliminary package substrate. The preliminary package substrate may include: the base substrate; a first conductive layer disposed on a first surface of the base substrate; a second conductive layer disposed on a second surface opposite to the first surface of the base substrate; the first solder resist layer disposed on the first surface of the base substrate; the second solder resist layer disposed on the second surface of the base substrate; and a plurality of contact plugs penetrating the base substrate and electrically connecting the first conductive layer and the second conductive layer.

In an embodiment, the interrupting process may include performing at least one of a drill process or a routing process.

The method may further include disposing a filler comprising a material having a high modulus and a low coefficient of thermal expansion in the plurality of stress relief through holes.

In an embodiment, forming the plurality of stress relief through holes may include forming each of the plurality of stress relief through holes as a single through hole extending continuously in a direction parallel to a plane of the package substrate.

In an embodiment, forming the plurality of stress relief through holes may include forming each of the plurality of stress relief through holes as a plurality of through holes arranged in a direction parallel to a plane of the package substrate and separated from each other.

According to one aspect of the present disclosure, a package substrate may include a plurality of unit substrates spaced apart from one another and imparting a stress on the package substrate. The package substrate may further include a base substrate; a first conductive layer disposed on a first surface of the base substrate; a second conductive layer disposed on a second surface of the base substrate opposite the first surface of the base substrate; a first solder resist layer disposed on the first surface of the base substrate; a second solder resist layer disposed on the second surface of the base substrate; a plurality of contact plugs penetrating the base substrate and electrically connecting the first conductive layer and the second conductive layer; and a plurality of stress relief through holes disposed adjacent to the plurality of unit substrates and penetrating the base substrate, the first solder resist layer and the second solder resist layer, and relieving at least a portion of the stress imparted on the package substrate by the plurality of unit substrates.

In an embodiment, each of the plurality of stress relief through holes may be disposed as a single through hole extending continuously in a direction parallel to a plane of the package substrate.

In an embodiment, each of the plurality of stress relief through holes may be disposed as a plurality of through holes arranged in a direction parallel to a plane of the package substrate and separated from each other.

In an embodiment, a stress relief through hole of the plurality of stress relief through holes may be disposed on a side of each unit substrate of the plurality of unit substrates.

In an embodiment, a stress relief through hole of the plurality of stress relief through holes may be disposed at a corner of each unit substrate of the plurality of unit substrates.

In an embodiment, the plurality of stress relief through holes may be at least partially filled with a filler comprising a material having a high modulus and a low coefficient of thermal expansion.

In an embodiment, the filler may include at least one of a metal or a polymer resin.

In the present disclosure, by performing the interrupting process on the unit substrate or the package substrate to form stress relief through holes, residual stresses within the package substrate may be released and the accumulation of stresses between materials may be reduced, thereby greatly reducing the accumulation of warpage of the package substrate. In addition, the material having a high modulus and a low coefficient of thermal expansion (CTE) may be further filled in the stress relief through hole to provide a supporting skeleton in the package substrate and improve the mismatch of CTEs of the materials in the package substrate, so that the warpage of the package substrate may be further reduced. Thus, the package performance of the package substrate may be improved.

### BRIEF DESCRIPTION OF THE DRAWINGS

These and/or other aspects will become apparent and more easily understood from the following description of embodiments taken in conjunction with the accompanying drawings, in which:

FIG. 1 is a diagram illustrating non-wet defect between a chip and a warped package substrate;

FIG. 2 is a plan view illustrating a package substrate having stress relief through holes according to an embodiment of the present disclosure;

FIG. 3 is a cross-sectional view illustrating the package substrate along a line III-III′ of FIG. 2 according to an embodiment of the present disclosure;

FIGS. 4-14 are plan views illustrating package substrates having stress relief through holes according to an embodiment of the present disclosure;

FIG. 15 is a plan view illustrating a package substrate having stress relief through holes including a filler according to an embodiment of the present disclosure;

FIG. 16 is a cross-sectional view illustrating the package substrate of FIG. 15 according to an embodiment of the present disclosure;

FIG. 17 is a flowchart illustrating a method of manufacturing a package substrate according to an embodiment of the present disclosure; and

FIG. 18 is a flowchart illustrating a method of manufacturing a package substrate according to an embodiment of the present disclosure.

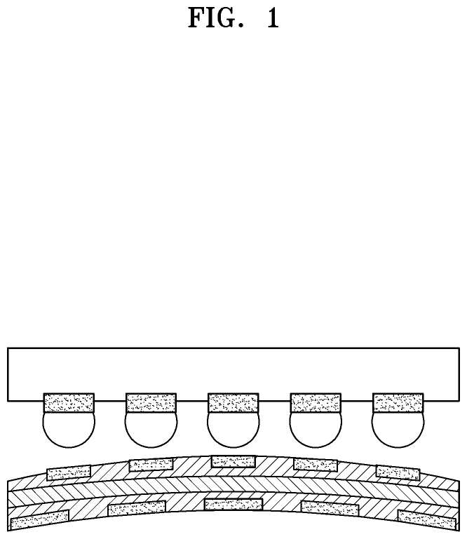

### DETAILED DESCRIPTION

Embodiments of the present disclosure will be more fully described with reference to the accompanying drawings in which exemplary embodiments of the present disclosure are illustrated. However, the present disclosure may be implemented in many different forms, and should not be constructed as being limited to embodiments set forth herein. Rather, embodiments are provided so that the present disclosure will be thorough and complete, and will fully convey the concept of the present disclosure to those of ordinary skill in the art.

Unless otherwise defined, all terms (including technical and scientific terms) used herein have the same meanings as commonly understood by those of ordinary skill in the art of which the present disclosure is a part. Terms, such as those defined in commonly used dictionaries, should be interpreted as having meanings that are consistent with their meanings in the context of the relevant art, and will not be interpreted in an idealized or overly formal sense unless expressly so defined herein.

In the following description, for the purposes of explanation, numerous specific details are set forth to provide a thorough understanding of various exemplary embodiments. It is apparent, however, that various exemplary embodiments may be practiced without these specific details or with one or more equivalent arrangements.

An anti-warp package substrate and a method of manufacturing the same according to a concept of the present disclosure will be described in detail below with reference to the accompanying drawings.

In an embodiment of the present disclosure, a plurality of unit substrates may impart a stress on a package substrate, and, the stress may be concentrated at the plurality of unit substrates, and warpage of the package substrate may be reduced. More particularly, warpage of an entire package substrate may be reduced by relieving stresses at portions of the package substrate between the plurality of unit substrates, which may reduce or prevent stress in the package substrate. For example, stress relief through holes may be disposed between the unit substrates, and the stress relief through holes may interrupt the package substrate. The stress relief through holes may release residual stresses within the package substrate and reduce an accumulation of stresses between materials. The stress relief through holes may reduce the accumulation of warpage of the package substrate. In addition, the stress relief through holes may be at least partially filled with a material having a high modulus and a low coefficient of thermal expansion (CTE) to provide a supporting skeleton in the package substrate. The stress relief through holes at least partially filled with a material having a high modulus and a low coefficient of thermal expansion (CTE) may improve the mismatch of CTEs of the materials in the package substrate, and may reduce the warpage of the package substrate.

In an embodiment of the present disclosure, stress relief through holes may be disposed at an edge region of a package substrate, which may interrupt the package substrate and reduce or prevent warpage at the edge region of the package substrate due to an accumulation of stresses. Further, residual stresses within the package substrate may be released and the accumulation of stresses between materials may be reduced, which may reduce warpage of the package substrate. In addition, the stress relief through holes may be at least partially filed with a material having a high modulus and a low coefficient of thermal expansion (CTE). For example, a modulus of the material may be higher than a modulus of the base substrate, and/or a CTE of the material may be lower than a CTE of the base substrate. The stress relief through holes having a material having a high modulus and a low coefficient of thermal expansion (CTE) may provide a supporting skeleton in the package substrate and improve a mismatch of CTEs of the materials in the package substrate, and may reduce the warpage of the package substrate.

For the convenience of description, plan views and cross-sectional views of the package substrate are schematically illustrated; however, the present disclosure is not limited thereto.

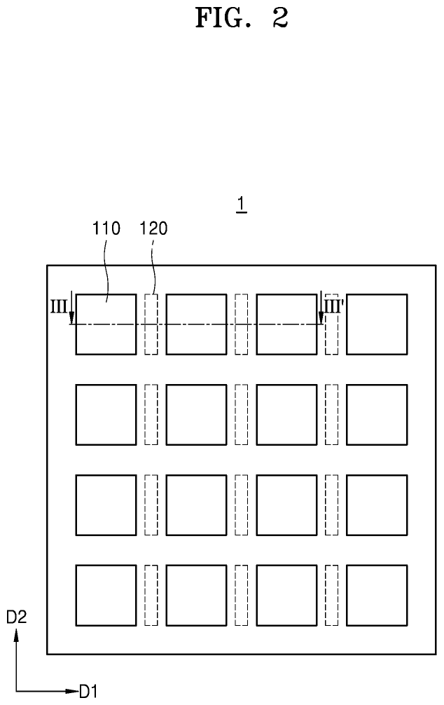

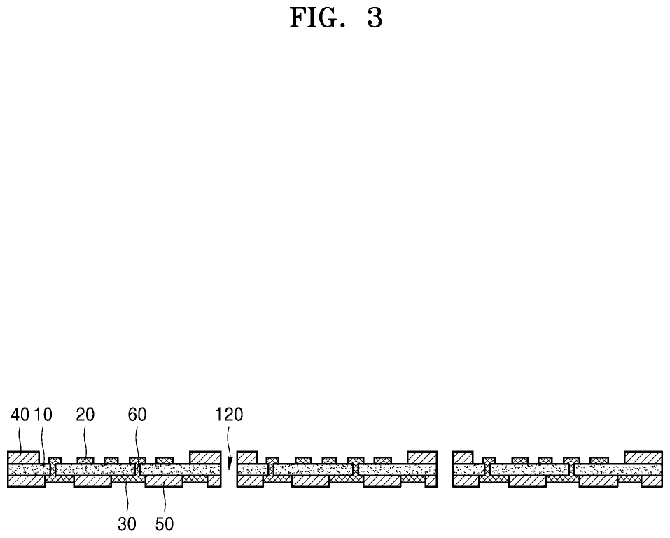

FIG. 2 is a plan view illustrating a package substrate having stress relief through holes according to an embodiment of the present disclosure. FIG. 3 is a cross-sectional view illustrating the package substrate along a line III-III′ of FIG. 2 according to an embodiment of the present disclosure.

With reference to FIG. 2 and FIG. 3, a package substrate 1 according to an embodiment of the present disclosure may include a base substrate 10, a first conductive layer 20 disposed on a first surface of the base substrate 10, and a second conductive layer 30 disposed on a second surface opposite to the first surface of the base substrate 10. The package substrate 1 may include a first solder resist layer 40 disposed on the first surface of the base substrate 10, and a second solder resist layer 50 disposed on the second surface of the base substrate 10. The package substrate 1 may include a contact plug 60 penetrating the base substrate 10 and electrically connecting the first conductive layer 20 and the second conductive layer 30 to each other. The first surface of the base substrate 10 may be a top surface of the base substrate 10, and the second surface of the base substrate 10 may be a bottom surface of the base substrate 10. Portions of the first solder resist layer 40 may be disposed on the first conductive layer 20, and portions of the second solder resist layer 50 may be disposed on the second conductive layer 30. For example, portions of the first conductive layer 20 may be disposed between the first solder resist layer 40 and the base substrate 10, and portions of the second conductive layer 30 may be disposed between the second solder resist layer 50 and the base substrate 10.

The base substrate 10 may be a silicon substrate, a silicon-germanium substrate, a germanium substrate, or a structure including a single crystal silicon substrate and a single crystal epitaxial layer grown therefrom.

In the plan view, according to positions of the first conductive layer 20, the second conductive layer 30, the first solder resist layer 40 and the second solder resist layer 50 included in the package substrate 1, the package substrate 1 may be divided by a plurality of unit substrates 110. Each of the unit substrates 110 may have, for example, a rectangular shape, such as a square shape. However, the shape of the unit substrate 110 is not limited thereto, and the unit substrate 100 may have another shape. The plurality of unit substrates 110 may be arranged on the package substrate 1 and separated from one another. The plurality of unit substrates 110 may be arranged in, for example, a matrix form, in the package substrate 1. A plurality of chips may be disposed on the plurality of unit substrates 110, respectively.

A plurality of stress relief through holes 120 may be disposed in the package substrate 1. More particularly, the plurality of stress relief through holes 120 may be disposed to penetrate the entire package substrate 1 in a thickness direction. For example, the plurality of stress relief through holes 120 may extend from an upper surface of the first solder resist layer 40 to a lower surface of the second solder resist layer 50 in the thickness direction. The plurality of stress relief through holes 120 may be exposed through the upper surface of the first solder resist layer 40 and the lower surface of the second solder resist layer 50. The plurality of stress relief through holes 120 may not pass through the first conductive layer 20 and the second conductive layer 30. For example, the plurality of stress relief through holes 120 may not come into contact with the first conductive layer 20 and the second conductive layer 30. The plurality of stress relief through holes 120 may be non-conductive. For example, the plurality of stress relief through holes 120 may not transmit electric signals.

In an embodiment, the stress relief through holes 120 may be disposed with respect to the unit substrates 110. More particularly, a stress relief through hole 120 may be disposed between unit substrates 110. As illustrated in FIG. 2, a stress relief through hole 120 may be disposed between unit substrates 110 adjacent to each other along a first direction D1. In this case, the unit substrates 110 adjacent to each other along the first direction D1 may share a stress relief through hole 120. It can be seen from FIG. 2 that the stress relief through holes 120 may be arranged in a matrix form in the plan view. However, the present disclosure is not limited to that illustrated in FIG. 2, and a stress relief through hole may be disposed between unit substrates 110 adjacent to each other along a second direction D2.

The first direction D1 and the second direction D2 may define a plane of the package substrate 1. As illustrated in FIG. 2, each stress relief through hole 120 may be disposed as a single through hole extending continuously in a direction parallel to the plane of the package substrate. More particularly, each stress relief through hole 120 may be disposed as a single through hole extending continuously along a respective side of the unit substrate 110. In a plan view, as illustrated in FIG. 2, the single through hole (or stress relief through hole 120) may have a rectangular shape; however, according to the inventive concept, the shape thereof is not limited thereto. In addition, a size (e.g., width) of the stress relief through hole 120 is not particularly specified, as long as the stress relief through hole 120 does not have an influence on the property of the unit substrate. In the plan view, the stress relief through hole 120 and the unit substrate 110 adjacent thereto may be spaced apart from each other by a particular distance.

In the package substrate 1, a residual stress within the package substrate 1 may be released by disposing a stress relief through hole 120 with the a through hole extending continuously between unit substrates 110 adjacent to each other along a direction, which may reduce or prevent the accumulation of stresses in the package substrate 1 due to stress diffusion between adjacent unit substrates 110. Accordingly, the warpage accumulation of the package substrate 1 may be reduced, and the warpage of the entire package substrate 1 may be reduced.

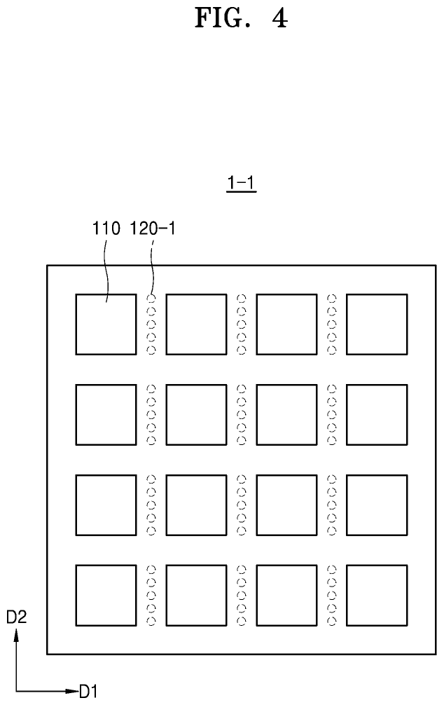

FIG. 4 is a plan view illustrating a package substrate having stress relief through holes according to an embodiment of the present disclosure, wherein FIG. 4 corresponds to FIG. 2. In FIG. 4, differences from the package substrate illustrated in FIG. 2 and FIG. 3 will be described and repetitive descriptions thereof may be omitted.

In an embodiment, unlike FIG. 2, a stress relief through hole 120-1 between unit substrates 110 adjacent to each other may be disposed as a plurality of through holes separated from each other instead of a single through hole extending continuously in a direction parallel to the plane of the package substrate. For example, one stress relief through hole 120-1 may be disposed as a plurality of through holes arranged in a direction parallel to the plane of the package substrate and separated from each other between two unit substrates 110 adjacent to each other. Each of the plurality of through holes of the stress relief through hole 120-1 may be disposed to penetrate the entire package substrate 1 in the thickness direction.

With reference to FIG. 4, a stress relief through hole 120-1 disposed between unit substrates 110 adjacent to each other along the first direction D1 may be formed of a plurality of through holes separated from each other. Alternatively, a stress relief through hole disposed between unit substrates 110 adjacent to each other along the second direction D2 may be formed of a plurality of through holes separated from each other.

As illustrated in FIG. 4, a shape of the plurality of through holes included in one stress relief through hole 120-1 may be circular in the plan view, but is not limited thereto. For example, shapes of the plurality of through holes in the plan view may be triangles, quadrilaterals (e.g., rectangles or squares having rounded corners), hexagons, ovals, and the like. In addition, the plurality of through holes may have the same or different shapes as/from each other in the plan view. The plurality of through holes may be uniformly arranged along respective sides of the unit substrate 110 and spaced apart from each other by a distance, but are not limited thereto.

According to the present disclosure, residual stress within the package substrate 1-1 may be released by disposing a stress relief through hole 120-1 including a plurality of through holes separated from each other between unit substrates 110 adjacent to each other along a direction. The stress relief through hole 120-1 including a plurality of through holes separated from each other between unit substrates 110 adjacent to each other along a direction may reduce or avoid the accumulation of stresses in the package substrate 1-1 due to stress diffusion between adjacent unit substrates 110. Thus, the warpage accumulation of the package substrate 1-1 may be reduced, and the warpage of the entire package substrate 1-1 may be reduced.

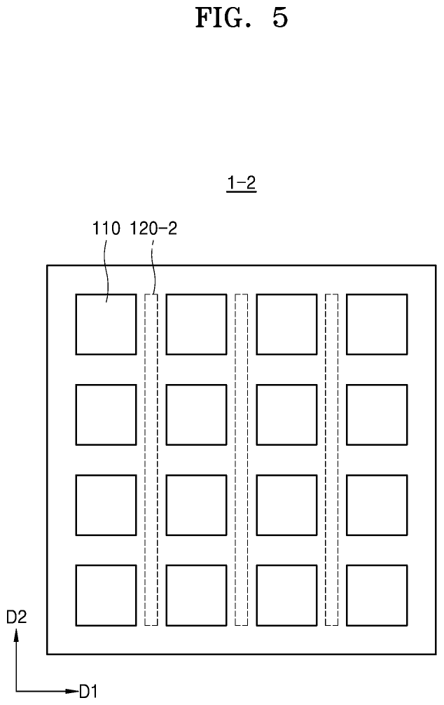

FIG. 5 is a plan view illustrating a package substrate having stress relief through holes according to an embodiment of the present disclosure, wherein FIG. 5 corresponds to FIG. 2. In FIG. 5, differences from the package substrate illustrated in FIGS. 2-4 will be described and repetitive descriptions thereof may be omitted.

In a package substrate 1-2 according to an embodiment, unlike FIG. 2, the stress relief through holes disposed in a same line may be combined with each other to form a larger stress relief through hole 120-2. For example, one stress relief through hole 120-2 may be disposed between lines (e.g., two rows or two columns) of unit substrates 110 adjacent to each other.

With reference to FIG. 5, a stress relief through hole 120-2 may be disposed between columns of unit substrates 110 adjacent to each other along the first direction D1. In this case, the columns of unit substrates 110 adjacent to each other along the first direction D1 may share one stress relief through hole 120-2. However, the present disclosure is not limited to that illustrated in FIG. 5, and a stress relief through hole may be disposed between rows of unit substrates 110 adjacent to each other along the second direction D2.

In FIG. 5, each stress relief through hole 120-2 may be disposed as a through hole extending continuously in a direction parallel to the plane of the package substrate. For example, one stress relief through hole 120-2 between two columns of unit substrates 110 adjacent to each other along the first direction D1 may be disposed as a single through hole.

However, the present disclosure is not limited thereto. Referring to FIG. 4 and FIG. 5, a stress relief through hole 120-2 disposed between lines of unit substrates 110 adjacent to each other may be formed of a plurality of through holes separated from each other. For example, a stress relief through hole 120-2 disposed between columns of unit substrates 110 adjacent to each other along the first direction D1 may include a plurality of through holes separated from each other. Alternatively, a stress relief through hole disposed between rows of unit substrates 110 adjacent to each other along the second direction D2 may include a plurality of through holes separated from each other.

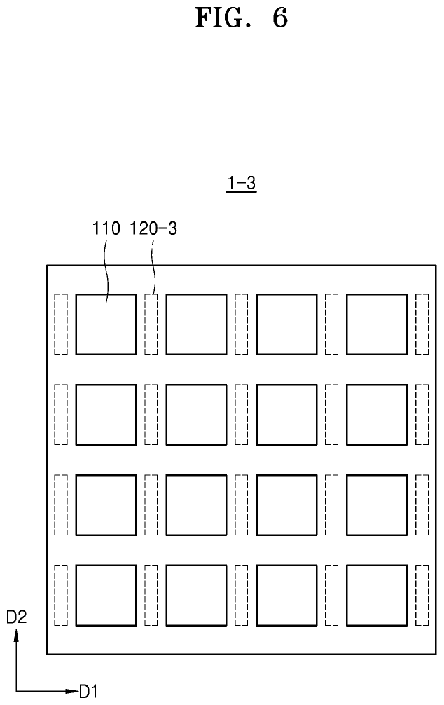

FIG. 6 is a plan view illustrating a package substrate having stress relief through holes according to an embodiment of the present disclosure. In FIG. 6, differences from the package substrate illustrated in FIGS. 2-4 will be described and repetitive descriptions thereof may be omitted.

In a package substrate 1-3 according to an embodiment, a number of stress relief through holes 120-3 may be disposed with respect to each unit substrate 110. For example, two stress relief through holes 120-3 may be disposed at two sides opposite to each other of each unit substrate 110, respectively.

With reference to FIG. 6, the stress relief through holes 120-3 may be disposed at both sides of a unit substrate 110 in the first direction D1, respectively. For example, the stress relief through holes 120-3 may be disposed at a left side and a right side of a unit substrate 110, respectively. In addition, the unit substrates 110 adjacent to each other in the first direction D1 may share a stress relief through hole 120-3. However, the present disclosure is not limited to that illustrated in FIG. 6, while a number of stress relief through holes may be disposed at both sides of a unit substrate 110 in the second direction D2, respectively. For example, the stress relief through holes may be disposed at an upper side and a lower side of a unit substrate 110, respectively.

As illustrated in FIG. 6, each stress relief through hole 120-3 may be disposed as a through hole extending continuously along a respective side of the unit substrate 110. For example, the stress relief through hole 120-3 at the left side of the unit substrate 110 may be disposed as a through hole extending continuously along the left side of the unit substrate 110, and the stress relief through hole 120-3 at the right side of the unit substrate 110 may be disposed as a through hole extending continuously along the right side of the unit substrate 110.

However, the present disclosure is not limited thereto. Referring to FIG. 4 and FIG. 6, stress relief through holes 120-3 respectively disposed at different sides of a unit substrate 110 in the first direction D1 may be formed of a plurality of through holes separated from each other. Alternatively, stress relief through holes respectively disposed at the different sides of a unit substrate 110 in the second direction D2 may be formed of a plurality of through holes separated from each other.

Referring to FIG. 5 and FIG. 6, the stress relief through holes 120-3 disposed in a line may be combined with each other to form a big stress relief through hole. In this case, the columns of unit substrates 110 adjacent to each other along the first direction D1 may share a stress relief through hole. Alternatively, a stress relief through hole may be disposed between rows of unit substrates 110 adjacent to each other along the second direction D2. Correspondingly, a stress relief through hole disposed between the lines of unit substrates 110 adjacent to each other may include a plurality of through holes separated from each other.

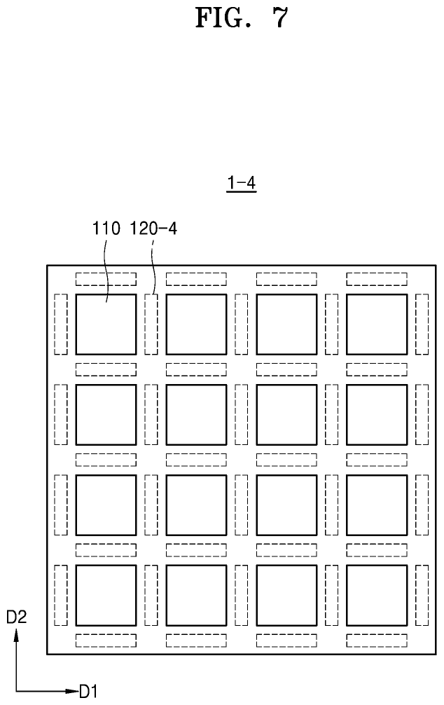

FIG. 7 is a plan view illustrating a package substrate having stress relief through holes according to an embodiment of the present disclosure. In FIG. 7, differences from the package substrate illustrated in FIGS. 2-4 will be described and repetitive descriptions thereof may be omitted.

In a package substrate 1-4 according to an embodiment, four stress relief through holes 120-4 may be disposed with respect to each unit substrate 110.

With reference to FIG. 7, four stress relief through holes 120-4 may be disposed at four sides of a unit substrate 110, respectively. The four stress relief through holes 120-4 extend along respective sides of the unit substrate 110, and have end portions at corner regions of the unit substrate 110. The four stress relief through holes 120-4 are disposed to be separated from each other instead of being continuous with each other to avoid separation of the unit substrate 110 therebetween from the package substrate 1-4. As illustrated in FIG. 7, the four stress relief through holes 120-4 may be disposed at a left side, a right side, an upper side, and a lower side of the unit substrate 110, respectively. In addition, two unit substrates 110 adjacent to each other in the first direction D1 may share a stress relief through hole 120-4, and two unit substrates 110 adjacent to each other in the second direction D2 may share a stress relief through hole 120-4.

As illustrated in FIG. 7, each stress relief through hole 120-4 may be disposed as a single through hole extending continuously along a respective side of the unit substrate 110. For example, the stress relief through hole 120-4 at the left side of the unit substrate 110 may be disposed as a single through hole extending continuously along the left side of the unit substrate 110, but is not limited thereto.

However, the present disclosure is not limited thereto. For example, referring to FIG. 4 and FIG. 7, the four stress relief through holes 120-4 respectively disposed at four sides of a unit substrate 110 may each be disposed as a plurality of through holes separated from each other.

Referring to FIG. 5 and FIG. 7, the stress relief through holes 120-4 disposed in a line may be combined with each other to form a big stress relief through hole. In this case, the two columns of unit substrates 110 adjacent to each other along the first direction D1 may share a stress relief through hole. Alternatively, a stress relief through hole may be disposed between two rows of unit substrates 110 adjacent to each other along the second direction D2. The stress relief through hole disposed between the two rows of unit substrates 110 adjacent to each other may include a plurality of through holes separated from each other.

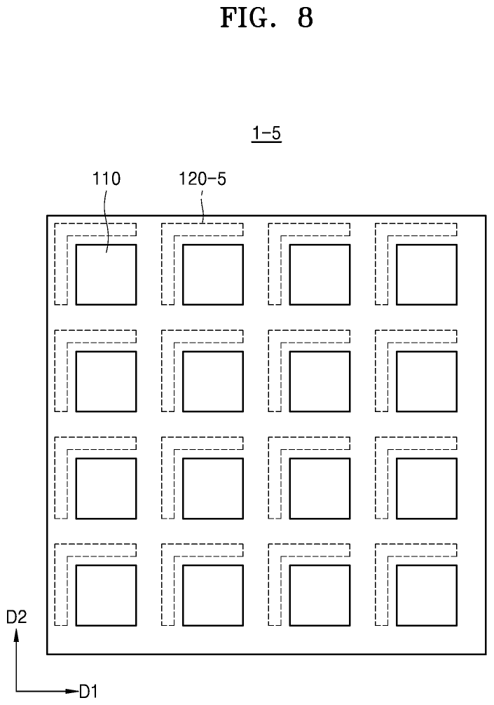

FIG. 8 is a plan view illustrating a package substrate having stress relief through holes according to an embodiment of the present disclosure. In FIG. 8, differences from the package substrate illustrated in FIGS. 2-4 will be described and repetitive descriptions thereof may be omitted.

In a package substrate 1-5 according to an embodiment, a stress relief through hole 120-5 may be disposed with respect to each unit substrate 110. More particularly, a stress relief through hole 120-5 may be disposed at different sides adjacent to each other of each unit substrate 110.

With reference to FIG. 8, a stress relief through hole 120-5 may be commonly disposed at the left side and the upper side adjacent to each other of each unit substrate 110. For example, a stress relief through hole 120-5 disposed around a unit substrate 110 may extend continuously from the left side of the unit substrate 110 to the upper side thereof and does not include an end portion at the corner.

As illustrated in FIG. 8, each stress relief through hole 120-5 may be disposed as a single through hole extending continuously along two sides adjacent to each other of the unit substrate 110. For example, as illustrated in FIG. 8, the stress relief through hole 120-5 may be disposed as a single through hole extending continuously along the left side and the upper side of the unit substrate 110.

However, the present disclosure is not limited thereto. Two stress relief through holes separated from each other and extending continuously along two sides adjacent to each other of the unit substrate 110 may be disposed around the unit substrate 110. For example, a single stress relief through hole extending continuously in directions parallel to the plane of the package substrate may be disposed at the upper side and the left side of the unit substrate 110, and a single stress relief through hole extending continuously in directions parallel to the plane of the package substrate may be disposed at the lower side and the right side of the unit substrate 110, wherein the two stress relief through holes have end portions at a lower left corner and an upper right corner.

However, the present disclosure is not limited thereto. For example, one stress relief through hole extending continuously may also be disposed at three sides adjacent to one another of one unit substrate 110. For example, stress relief through holes extending continuously along the left side, the upper side, and the right side of the unit substrate 110 may be disposed around it.

Referring to FIG. 4 and FIG. 8, a stress relief through hole 120-5 may be disposed at sides adjacent to each other of a unit substrate 110 and may include a plurality of through holes separated from each other. For example, the stress relief through hole 120-5 may extend along the left side and the upper side of the unit substrate 110 may include a plurality of through holes separated from each other. A stress relief through hole 120-5 formed of a plurality of through holes separated from each other may reduce or prevent separation of the unit substrate 110 from the package substrate 1-5.

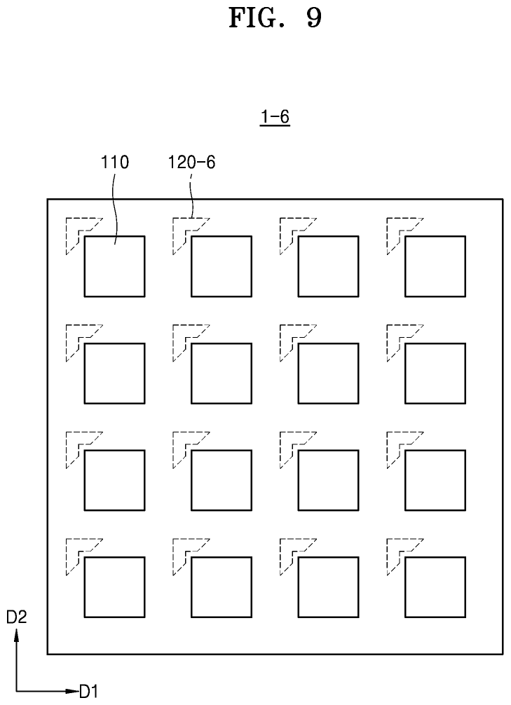

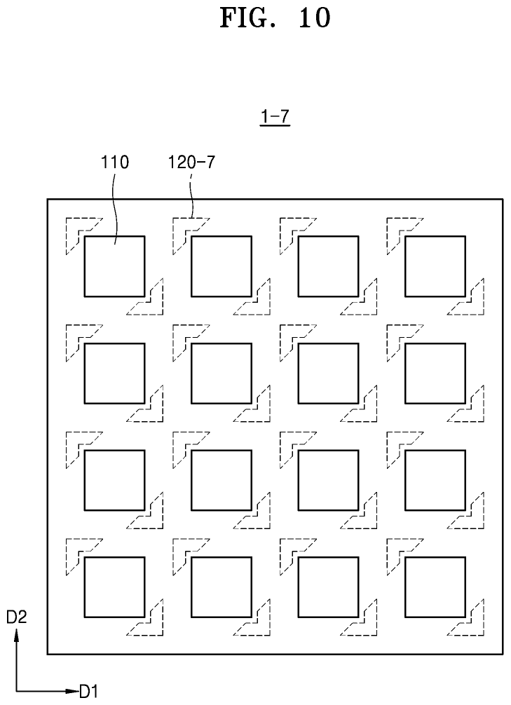

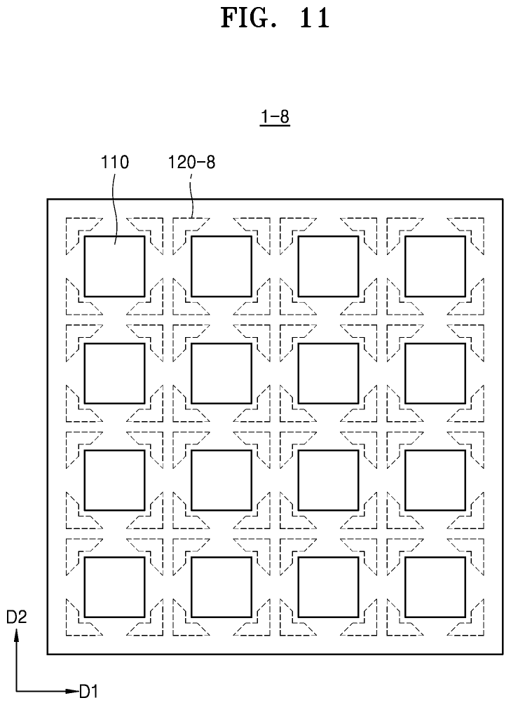

FIG. 9 is a plan view illustrating a package substrate having stress relief through holes according to an embodiment of the present disclosure. FIG. 10 is a plan view illustrating a package substrate having stress relief through holes according to an embodiment of the present disclosure. FIG. 11 is a plan view illustrating a package substrate having stress relief through holes according to an embodiment of the present disclosure. In FIGS. 9-11, differences from the package substrate illustrated in FIGS. 2-8 will be described and repetitive descriptions thereof may be omitted.

In a package substrate according to an embodiment, a stress relief through hole may be disposed at a corner of each unit substrate 110. More particularly, stress relief through holes may be disposed at one corner region, two corner regions, three corner regions or four corner regions of each unit substrate 110.

With reference to FIG. 9, in a package substrate 1-6 according to an embodiment, a stress relief through hole 120-6 may be disposed at an upper left corner of each unit substrate 110. However, the present disclosure is not limited to that illustrated in FIG. 9, while a stress relief through hole may be disposed at an upper right corner, a lower left corner, or a lower right corner of each unit substrate 110.

With reference to FIG. 10, in a package substrate 1-7 according to an embodiment, stress relief through holes 120-7 may be disposed at corner regions on a diagonal of each unit substrate 110, respectively. For example, as illustrated in FIG. 10, stress relief through holes 120-7 may be disposed at an upper left corner and a lower right corner of each unit substrate 110, respectively. However, the present disclosure is not limited to that illustrated in FIG. 10, and stress relief through holes may be disposed at an upper right corner and a lower left corner of each unit substrate 110, respectively.

Alternatively, stress relief through holes may be disposed at corner regions adjacent to each other of each unit substrate 110, respectively. For example, two stress relief through holes may be disposed at the upper left corner and the upper right corner, the upper left corner and the lower left corner, the upper right corner and the lower right corner, or the lower left corner and the lower right corner of each unit substrate 110, respectively.

With reference to FIG. 11, in a package substrate 1-8 according to an embodiment, stress relief through holes 120-8 may be disposed at corner regions of each unit substrate 110, respectively. For example, stress relief through holes 120-8 may be disposed at the upper left corner, the lower left corner, the upper right corner, and the lower right corner of each unit substrate 110, respectively.

In FIGS. 9-11, the stress relief through holes 120-6, 120-7 or 120-8 may be disposed as single through holes extending continuously in one or more directions parallel to the plane of the package substrate. The stress relief through holes 120-6, 120-7 or 120-8 may be conformally formed at corner regions of the unit substrate 110.

However, the present disclosure is not limited thereto. Referring to FIG. 4 and FIGS. 9-11, the stress relief through holes 120-6, 120-7 or 120-8 disposed at the corner regions of the unit substrate 110 may include a plurality of through holes separated from each other. The shapes of the stress relief through holes 120-6, 120-7 or 120-8 are not particularly limited.

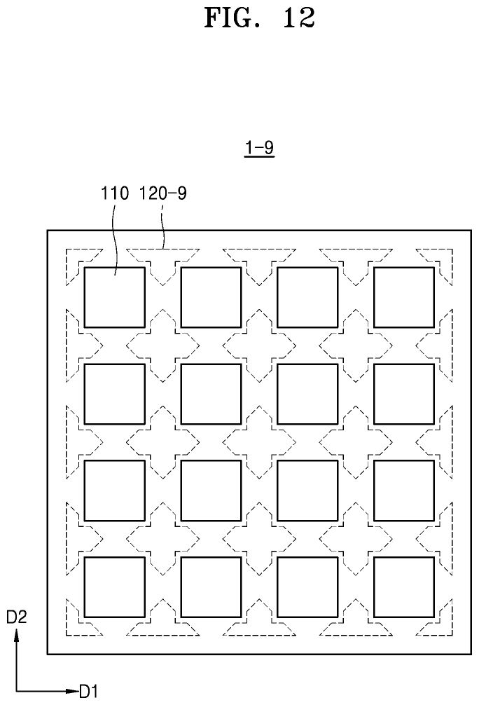

FIG. 12 is a plan view illustrating a package substrate having stress relief through holes according to an embodiment of the present disclosure. In FIG. 12, differences from the package substrate illustrated in FIGS. 2-11 will be described and repetitive descriptions thereof may be omitted.

With reference to FIG. 12, in a package substrate 1-9 according to an embodiment, stress relief through holes at adjacent corner regions may be combined with each other to form continuous stress relief through holes 120-9. In a plan view, the stress relief through hole 120-9 may have a T-shaped shape and/or a cross-shaped shape.

As illustrated in FIG. 12, the stress relief through hole 120-9 may be disposed as a single through hole extending continuously in one or more directions parallel to the plane of the package substrate. However, the present disclosure is not limited thereto. Referring to FIG. 4 and FIG. 12, the stress relief through hole 120-9 disposed at the corner of the unit substrate 110 may be formed of a plurality of through holes separated from each other.

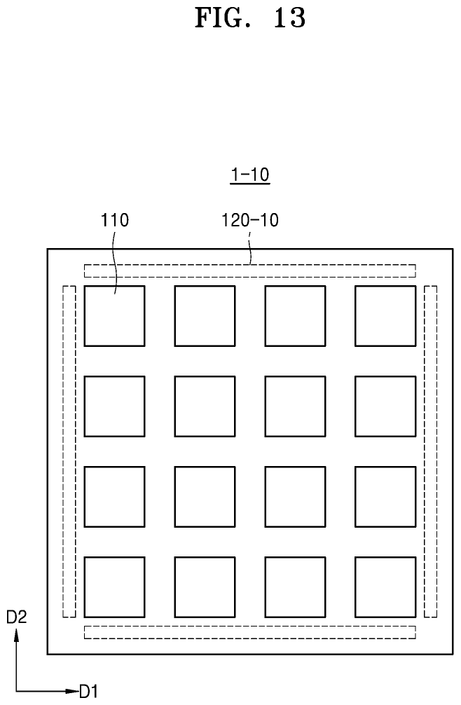

FIG. 13 is a plan view illustrating a package substrate having stress relief through holes according to an embodiment of the present disclosure. In FIG. 13, differences from the package substrate illustrated in FIGS. 2-12 will be described and repetitive descriptions thereof may be omitted.

In a package substrate 1-10 according to an embodiment, a stress relief through hole 120-10 may be disposed with respect to an entire package substrate 1-10.

With reference to FIG. 13, stress relief through holes 120-10 separated from each other may be disposed at edge regions of the entire package substrate 1-10, respectively. As illustrated in FIG. 13, stress relief through holes 120-10 may each be disposed at a left edge region, a right edge region, an upper edge region and a lower edge region of the entire package substrate 1-10. The stress relief through holes 120-10 may be disposed to be separated from each other instead of being continuous with each other to avoid separation of the unit substrate 110 therebetween from the package substrate 1-10.

However, the present disclosure is not limited to that illustrated in FIG. 13, and the stress relief through hole(s) may be disposed at one edge region, two edge regions or three edge regions of the entire package substrate 1-10. For example, two stress relief through holes may be disposed at two edge regions opposite to each other (e.g., a left edge region and a right edge region) of the entire package substrate 1-10, respectively.

As illustrated in FIG. 13, each stress relief through hole 120-10 may be disposed as a through hole extending continuously along a respective edge region of the package substrate 1-10. For example, the stress relief through hole 120-10 at the left edge region of the package substrate 1-10 may be disposed as a single through hole extending continuously along the left edge region of the package substrate 1-10, but is not limited thereto. However, the present disclosure is not limited thereto. Referring to FIG. 4 and FIG. 13, stress relief through holes 120-10 respectively disposed at edge regions of the entire package substrate 1-10 may be formed of a plurality of through holes separated from each other.

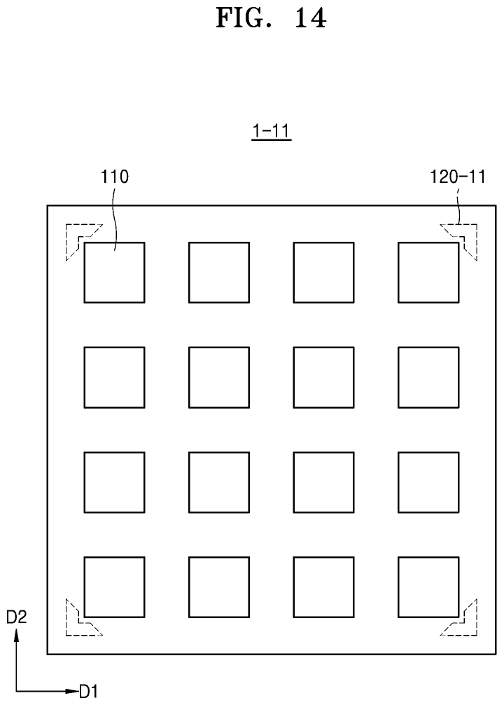

FIG. 14 is a plan view illustrating a package substrate having stress relief through holes according to an embodiment of the present disclosure. In FIG. 14, differences from the package substrate illustrated in FIGS. 2-13 will be described and repetitive descriptions thereof may be omitted.

In a package substrate 1-11 according to an embodiment, a stress relief through hole 120-11 may be disposed with respect to the entire package substrate 1-11.

With reference to FIG. 14, stress relief through holes 120-11 may be disposed at corner regions of the entire package substrate 1-11, respectively. For example, four stress relief through holes 120-11 may be disposed at an upper left corner, a lower left corner, an upper right corner, and a lower right corner of the entire package substrate 1-11, respectively.

However, the present disclosure is not limited to that illustrated in FIG. 14, and the stress relief through hole(s) may be disposed at one corner, two corner regions or three corner regions of the entire package substrate 1-11. For example, two stress relief through holes may be disposed at two corner regions on a diagonal (e.g., an upper left corner and a lower right corner) of the entire package substrate 1-11, respectively.

As illustrated in FIG. 14, the stress relief through hole 120-11 may be disposed as a through hole extending continuously in directions parallel to the plane of the package substrate. The stress relief through holes 120-11 may be conformally formed at corner regions of the unit substrate 110. However, the present disclosure is not limited thereto. For example, referring to FIG. 4 and FIG. 14, the stress relief through holes 120-11 respectively disposed at corner regions of the entire package substrate 1-11 may each be disposed as a plurality of through holes separated from each other. The shapes of the stress relief through holes 120-11 are not particularly limited.

Based on the present inventive concept, various modifications may be made on the layout of the stress relief through holes with respect to a single unit substrate or a plurality of unit substrates without being limited to those illustrated in FIGS. 2-14.

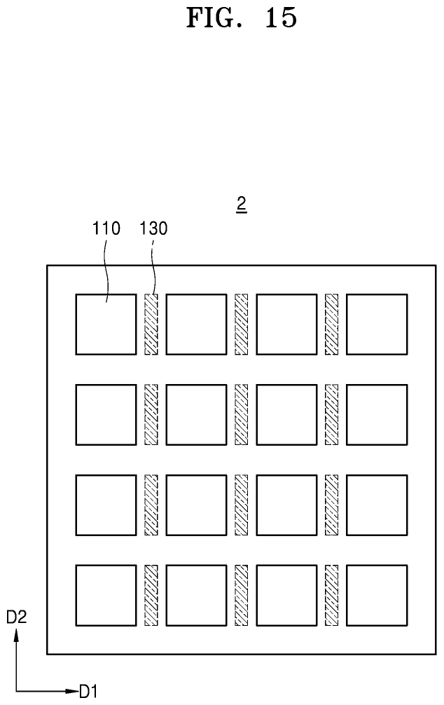

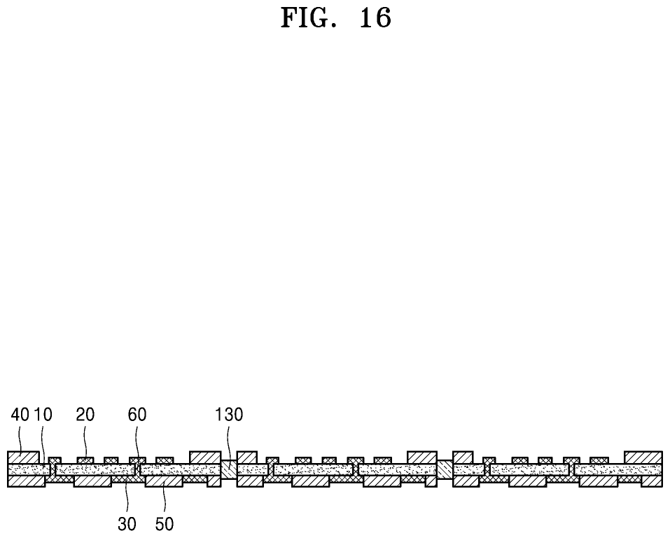

FIG. 15 is a plan view illustrating a package substrate having stress relief through holes including a filler according to an embodiment of the present disclosure. FIG. 16 is a cross-sectional view illustrating the package substrate of FIG. 15 according to an embodiment of the present disclosure.

For the convenience of description, in the present disclosure, embodiments of FIG. 15 and FIG. 16 may correspond to an embodiment of FIG. 2. However, the present disclosure is not limited thereto.

With reference to FIG. 2, FIG. 15, and FIG. 16, the stress relief through hole 120 may be at least partially filled with a filler 130. The filler 130 may improve the mismatch of CTEs of the materials. The filler may provide a support frame for the package substrate 2. In an embodiment, the filler 130 may include a material having a high modulus and a low thermal expansion coefficient. In an embodiment, the choice of the material having a high modulus and a low thermal expansion coefficient is not particularly limited, and a proper material may be selected according to the type of materials and the warpage control effect of the package substrate 2. For example, the material having a high modulus and a low thermal expansion coefficient may be a metal or a polymer resin. When the material having a high modulus and a low thermal expansion coefficient is the metal, the metal may preferably be copper, which may be an interconnection material used in the package substrate, but is not limited thereto. When the material having a high modulus and a low thermal expansion coefficient is the polymer resin, the polymer resin may preferably be an epoxy resin, but is not limited thereto. In an embodiment, the type of materials of the filler may be determined according to its effect for improving warpage, its bonding force with other materials around it and the feasibility of processing process, etc., and is not limited to those listed herein.

The material having a high modulus and a low thermal expansion coefficient may at least partially fill the stress relief through hole 120, and may form a supporting skeleton in the package substrate 2. The material having a high modulus and a low thermal expansion coefficient disposed in the stress relief through hole 120 may improve the mismatch of CTEs of the materials in the package substrate 2, and the warpage of the package substrate 2 may be further reduced.

According to the concept of the present disclosure, the stress relief through holes that are disposed as single through holes or a plurality of through holes in FIGS. 4-14 may be at least partially filled with the material having a high modulus and a low thermal expansion coefficient such as the metal or the polymer resin as illustrated in FIG. 15 and FIG. 16. The material having a high modulus and a low thermal expansion coefficient may provide a supporting skeleton in the package substrate, and may improve the mismatch of CTEs of the materials in the package substrate, so that the warpage of the package substrate may be further reduced. However, the present disclosure is not limited thereto.

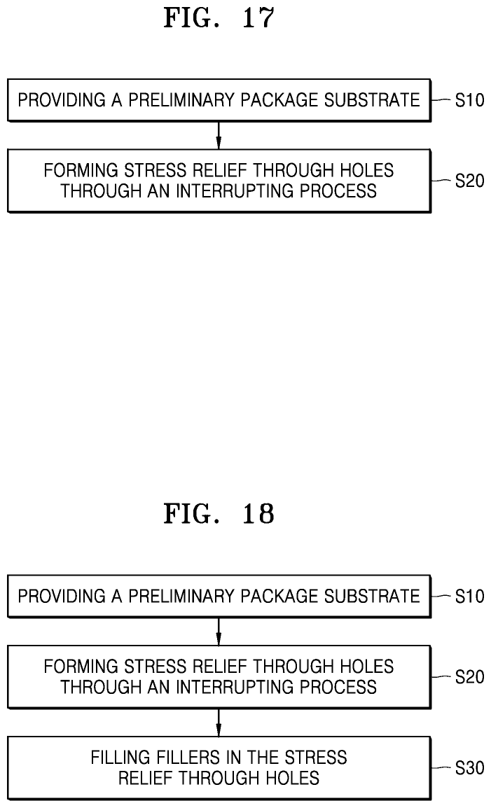

FIG. 17 is a flowchart illustrating a method of manufacturing a package substrate according to an embodiment of the present disclosure. In detail, the manufacturing method illustrated in FIG. 17 corresponds to the package substrate 1 of FIG. 2.

With reference to FIG. 2, FIG. 3, and FIG. 17, a preliminary package substrate may be provided (S10). The preliminary package substrate may include a base substrate 10, a first conductive layer 20 disposed on a first surface of the base substrate 10, a second conductive layer 30 disposed on a second surface opposite to the first surface of the base substrate, a first solder resist layer 40 disposed on the first conductive layer 20, a second solder resist layer 50 disposed on the second conductive layer 30, and a contact plug 60 penetrating the base substrate 10 and electrically connecting the first conductive layer 20 and the second conductive layer 30 to each other. The first surface of the base substrate 10 may be a top surface of the base substrate 10, and the second surface of the base substrate 10 may be a bottom surface of the base substrate 10.

In a plan view, the preliminary package substrate may be include a plurality of unit substrates 110. One or more of the plurality of unit substrates 110 may include one or more chips disposed thereon.

An interrupting process may be performed on the preliminary package substrate with respect to each unit substrate 110, which may form stress relief through holes 120 (S20), thereby manufacturing the package substrate 1 having the stress relief through hole 120 as illustrated in FIG. 2. With reference to FIG. 2, the interrupting process may be performed between two unit substrates 110 adjacent to each other along a first direction D1, to form a stress relief through hole 120 that is disposed as a single through hole and extends along a second direction D2. The interrupting process may be executed through a drill process or a routing process; however, the present disclosure is not limited thereto, and any suitable process may be used.

The stress relief through hole 120 may penetrate the entire preliminary package substrate in the thickness direction. For example, the stress relief through hole 120 may extend in the thickness direction from an upper surface of the first solder resist layer 40 to a lower surface of the second solder resist layer 50, and be exposed through the upper surface of the first solder resist layer 40 and the lower surface of the second solder resist layer 50.

Alternatively, with reference to FIGS. 4-14, the interrupting process may be performed on the preliminary package substrate according to the position and the shape of the stress relief through holes to be formed to form respective stress relief through holes, thereby manufacturing a package substrate including the stress relief through holes illustrated in FIGS. 4-14.

FIG. 18 is a flowchart illustrating a method of manufacturing a package substrate according to an embodiment of the present disclosure. In detail, the manufacturing method illustrated in FIG. 18 corresponds to the package substrate 2 of FIG. 15.

With reference to FIG. 2, FIG. 3, FIG. 15, FIG. 16 and FIG. 18, a preliminary package substrate which can be divided into a plurality of unit substrates 110 may be provided (S10).

An interrupting process may be performed on the preliminary package substrate with respect to each unit substrate 110, to form stress relief through holes 120 (S20).

With reference to FIG. 2, the interrupting process may be performed between two unit substrates 110 adjacent to each other along the first direction D1, to form a stress relief through hole 120 that is disposed as a single through hole and extends along the second direction D2. The stress relief through hole 120 may penetrate the entire preliminary package substrate in the thickness direction.

A filler 130 may be deposited in the stress relief through hole 120 (S30), thereby manufacturing the package substrate 2 having the stress relief through hole 120 in which the filler 130 is disposed as illustrated in FIG. 15. The filler 130 may include a material having a high modulus and a low thermal expansion coefficient. For example, the material having a high modulus and a low thermal expansion coefficient may be a metal such as copper or a polymer resin. In an embodiment, the filling operation may be executed through an electroplating process or a screen printing process; however, the present disclosure is not limited thereto, and any proper process may be used.

Alternatively, with reference to FIGS. 2-14, the filler 130 may be disposed in the stress relief through hole illustrated in FIGS. 2-14, thereby manufacturing a package substrate having stress relief through holes including a filler therein. The filler may at least partially fill the stress relief through hole illustrated in FIGS. 2-14.

In an embodiment, the filler 130 may have a side surface according to an interrupting process to form the plurality of stress relief through holes. For example, when a drill process or a routing process is used in the interrupting process, the side surface of the filler 130 may have a drilled shape. In another example, when a laser process is used in the interrupting process, the filler 130 may have a side surface reflecting the laser process. Accordingly, the side surface of the filler 130 may have a different shape from a side surface of another penetrating element such as a contact plug 60. For example, the side surfaces of the contact plug 60 and the filler 130 may have different profiles.

Although embodiments of the present disclosure have been described for the purpose of explanation, it will be understood by those of ordinary skill in the art that various modifications and replacements are possible without departing from the spirit or scope of the present disclosure as disclosed in the appended claims. In addition, embodiments disclosed in the present disclosure are not intended to limit the technical spirit of the present disclosure, and all technical concepts within the scope of the appended claims and equivalents thereof should be interpreted as being included in the scope of the present disclosure.

What is claimed is:

1. A package substrate divided by a plurality of unit substrates, the package substrate comprising:
a base substrate;
a first conductive layer disposed on a first surface of the base substrate;
a second conductive layer disposed on a second surface of the base substrate opposite the first surface of the base substrate;
a first solder resist layer disposed on the first surface of the base substrate;
a second solder resist layer disposed on the second surface of the base substrate;
a plurality of contact plugs penetrating the base substrate and electrically connecting the first conductive layer and the second conductive layer; and
a plurality of stress relief through holes penetrating the base substrate, the first solder resist layer and the second solder resist layer.

2. The package substrate of claim 1, wherein each of the plurality of stress relief through holes is disposed as a single through hole extending continuously in a direction parallel to a plane of the package substrate.

3. The package substrate of claim 1, wherein each of the plurality of stress relief through holes is disposed as a plurality of through holes arranged in a direction parallel to a plane of the package substrate and separated from each other.

4. The package substrate of claim 1, wherein at least a portion of each the plurality of stress relief through holes is disposed between adjacent unit substrates of the plurality of unit substrates.

5. The package substrate of claim 1, wherein a stress relief through hole of the plurality of stress relief through holes is disposed on a side of each unit substrate of the plurality of unit substrates.

6. The package substrate of claim 1, wherein a stress relief through hole of the plurality of stress relief through holes is disposed at a corner portion of each unit substrate of the plurality of unit substrates.

7. The package substrate of claim 1, wherein the plurality of stress relief through holes are disposed with respect to an entirety of the package substrate, and disposed at at least one of four edge regions and at at least one of four corner regions of the package substrate.

8. The package substrate of claim 1, wherein the plurality of stress relief through holes are at least partially filled with a filler comprising a material having a high modulus and a low coefficient of thermal expansion.

9. A method of manufacturing a package substrate, comprising:
providing a preliminary package substrate including a plurality of unit substrates, the preliminary package substrate comprising a base substrate, a first conductive layer disposed on a first surface of the base substrate, a second conductive layer disposed on a second surface opposite to the first surface of the base substrate, a first solder resist layer disposed on the first surface of the base substrate, a second solder resist layer disposed on the second surface of the base substrate, and a plurality of contact plugs penetrating the base substrate and electrically connecting the first conductive layer and the second conductive layer; and
performing an interrupting process on the preliminary package substrate to form a plurality of stress relief through holes penetrating the base substrate, the first solder resist layer and the second solder resist layer.

10. The method of claim 9, wherein the interrupting process comprises performing at least one of a drill process or a routing process.

11. The method of claim 9, further comprising disposing a filler comprising a material having a high modulus and a low coefficient of thermal expansion in the plurality of stress relief through holes.

12. The method of claim 9, wherein forming the plurality of stress relief through holes comprises forming each of the plurality of stress relief through holes as a single through hole extending continuously in a direction parallel to a plane of the package substrate.

13. The method of claim 9, wherein forming the plurality of stress relief through holes comprises forming each of the plurality of stress relief through holes as a plurality of through holes arranged in a direction parallel to a plane of the package substrate and separated from each other.

14. A package substrate including a plurality of unit substrates spaced apart from one another and imparting a stress on the package substrate, the package substrate comprising:
a base substrate;
a first conductive layer disposed on a first surface of the base substrate;
a second conductive layer disposed on a second surface of the base substrate opposite the first surface of the base substrate;
a first solder resist layer disposed on the first surface of the base substrate;
a second solder resist layer disposed on the second surface of the base substrate;
a plurality of contact plugs penetrating the base substrate and electrically connecting the first conductive layer and the second conductive layer; and
a plurality of stress relief through holes disposed adjacent to the plurality of unit substrates and penetrating the base substrate, the first solder resist layer and the second solder resist layer, and relieving at least a portion of the stress imparted on the package substrate by the plurality of unit substrates.

15. The package substrate of claim 14, wherein each of the plurality of stress relief through holes is disposed as a single through hole extending continuously in a direction parallel to a plane of the package substrate.

16. The package substrate of claim 14, wherein each of the plurality of stress relief through holes is disposed as a plurality of through holes arranged in a direction parallel to a plane of the package substrate and separated from each other.

17. The package substrate of claim 14, wherein a stress relief through hole of the plurality of stress relief through holes is disposed on a side of each unit substrate of the plurality of unit substrates.

18. The package substrate of claim 14, wherein a stress relief through hole of the plurality of stress relief through holes is disposed at a corner of each unit substrate of the plurality of unit substrates.

19. The package substrate of claim 14, wherein the plurality of stress relief through holes are at least partially filled with a filler comprising a material having a high modulus and a low coefficient of thermal expansion.

20. The package substrate of claim 19, wherein the filler includes at least one of a metal or a polymer resin.
